(19) United States
(12) Patent Application Publication
(10) Pub. No.: US 2007/0264842 A1
(43) Pub. Date: Nov. 15, 2007

(54) Insulation film deposition method for a semiconductor device

(75) Inventor: Yong-Geun Kim, Cheonan-si (KR)

Correspondence Address: F. CHAU & ASSOCIATES, LLC, 130 WOODBURY ROAD, WOODBURY, NY, 11797, US

(73) Assignee: Samsung Electronics Co., Ltd., Suwon-si (KR)

(21) Appl. No.: 11/582,292

(22) Filed: Oct. 17, 2006

(30) Foreign Application Priority Data
May 12, 2006 (KR) 2006-0042857

(51) Int. Cl. H01L 21/31; H01L 21/469

(52) U.S. Cl. 438/770

(57) ABSTRACT

A thin-film deposition method for a semiconductor device includes injecting a process gas into a process chamber to deposit a thin film and forming a plasma atmosphere inside the process chamber while injecting the process gas to deposit a thin film on a semiconductor substrate. The thin film is formed by a reaction between the process gas and the plasma.

### CROSS-REFERENCE TO RELATED APPLICATION

This application claims priority from Korean Patent Application No. 10-2006-0042857, filed on May 12, 2006, the disclosure of which is hereby incorporated by reference herein in its entirety.

### BACKGROUND OF THE INVENTION

1. Technical Field

The present disclosure relates to a semiconductor device manufacturing method, and more particularly to an insulating film deposition method for a semiconductor device.

2. Description of the Related Art

As a result of the rapid development of both the information communication field as well as information media such as, for example, computers, the demand for semiconductor devices which exhibit high-speed operation and large storage capability has increased. Accordingly, the integration of semiconductor devices have also been increased in response to the above demand.

However, as a result of the increase in the integration of semiconductor devices, it may now be more difficult to obtain precise profiles because resolution may be decreased during a photolithography process. Further, misalignment may be induced due to a lack of process margin caused by the decrease of the design rule, thereby possibly lowering the reliability and productivity of the semiconductor device.

Accordingly, to solve above-mentioned difficulties, a conventional high integration technique has been developed that can form a multi-layer structure within a limited region. In the high integration technique, a double-layer process for connecting one or more metal layers through a metal via contact as well as a lamination process for forming two or more transistors in a vertical structure on the same vertical line of a semiconductor substrate has been developed.

However, to accomplish the above-mentioned conventional high integration technique, an insulating film interposed between circuit patterns should perform a sufficient insulating function. With this conventional technique, a spaced distance between the circuit patterns is gradually narrowed due to the decrease of the design rule caused by the high integration of the semiconductor device. Moreover, the electrical properties of the semiconductor devices are dependant on the insulating function of the insulating film that prevents an electric short between neighboring circuit patterns. The insulating film includes, for example, an isolation film for defining an active region and a field region, a gate oxidation film, and an interlayer insulating film consisting of various kinds of insulating materials. The interlayer insulating film for insulating neighboring conduction films can be formed of, for example, a hydrogen silsesquioxane (HSQ), a boron phosphorus silicate glass (BPSG), an undoped silicate glass (USG), a phosphorus silicate glass (PSG), a high density plasma (HDP) and a plasma enhanced tetraethyl orthosilicate (PETEOS). Among them, the PETEOS film is typically used as an inter-metal dielectric (IMD) isolating between metal layers because of having improved step coverage properties and insulating properties.

Usually, the PETEOS film is formed on a semiconductor substrate through processes for injecting gas-phase tetraethylorthosilicate (TEOS) chemicals into a process chamber to which O₂ gas flows, and after having a desired pause time for stabilizing the TEOS chemicals and applying a radio frequency (RF) power to the process chamber to form oxygen (O₂) plasma.

During this time, the TEOS chemicals are turned into a gas-phase using a heating unit and then injected into the process chamber. However, if a temperature for turning the TEOS chemicals into perfect gas phase is not arrived at, gas-phase TEOS chemicals and liquid-phase TEOS chemicals are injected into the process chamber. Accordingly, the PETEOS film is formed by reacting with O₂ plasma floating inside the process chamber during the pause time of about 10 seconds to stabilize the TEOS chemicals.

However, if the PETEOS film has the desired pause time after injecting the TEOS chemicals into the process chamber, some of liquid-phase TEOS chemicals, which are injected into the process chamber without being turned into the gas phase, are dropped onto a wafer surface by their own weight. In addition, gas-phase TEOS chemicals, which are injected into the process chamber, are also dropped onto the wafer surface due to the increase in their own weight caused by being recombined to the liquid-phase inside of the process chamber. These TEOS chemicals dropped onto the wafer surface do not react with O₂ plasma. Accordingly, particles are formed on the wafer surface.

FIG. 1 is a diagram illustrating a particle production map on a wafer surface, in which a PETEOS film deposition process is completed, according to the conventional art.

Referring to FIG. 1, when the PETEOS film is formed according to the conventional art, particles are produced on a surface of a wafer 10 by TEOS chemicals that are not reacted with plasma.

FIG. 2 is an expanded diagram for a wafer region (A) in which particles are produced.

Referring to FIG. 2, a particle 12 with a petal shape is formed on the surface of the wafer 10. The particle 12 is a size of about 0.2 to about 0.5 μm, and deteriorates the quality and dielectric properties of the PETEOS film.

Usually, the reliability and productivity of a semiconductor device are affected by fine dust in the atmosphere. When the petal shape's particle 12 having several hundreds of size, compared to the fine dust, is formed on a whole surface of the wafer 10, the reliability and productivity of the semiconductor device are adversely affected by deterioration of the dielectric properties of the PETEOS film. Further, in the case where the particle is separated from the wafer surface and attached on an inner wall of the process chamber, the the total process time is prolonged and the working ratio of facilities is lowered, because a cleaning process must be performed to remove the particle.

The semiconductor device is usually manufactured by depositing a thin film on the wafer surface, and patterning the thin film to form various circuit patterns. Unit processes for manufacturing the semiconductor device are mainly divided into an ion implantation process for implanting dopant ions consisting of group 3B or 5B elements into a semiconductor substrate, a thin-film deposition process for forming a material film on the semiconductor substrate, an etching process for forming the material film into a desired pattern, a chemical mechanical polishing (CMP) process for depositing an interlayer insulating film on the wafer surface and then collectively polishing the wafer surface to remove a step, and a cleaning process for cleaning the wafer and a chamber to remove impurities. Accordingly, to manufacture the semiconductor device, the unit processes are repeatedly performed using each of the process chambers.

In particular, the thin-film deposition process among them is one of main processes that are performed to form the material film performing various functions on the wafer surface. The thin-film deposition process applies various techniques such as, for example, physical vapor deposition (PVD), chemical vapor deposition (CVD), a plasma enhanced chemical vapor deposition (PECVD), rapid thermal anneal (RTA), and others, to form a conduction film and an insulation film.

The term “TEOS” is a kind of SiO₂ film that is produced by hydrolysis of liquid materials such as, for example, tetraethoxysilane Si(OC₂H₅)₄) in a vacuum, and is used as inter metal dielectric film because of having improved step coverage and dielectric properties, when the semiconductor device is fabricated.

The term “PETEOS” is also a kind of silicon dioxide (SiO₂) film that is deposited by a chemical reaction of plasma and gas-phase TEOS chemicals formed by applying RF power under a desired temperature and pressure atmosphere.

This PETEOS film is formed by turning liquid-phase TEOS chemicals to gas-phase TEOS chemicals using the heating unit, and then performing the chemical reaction of the gas-phase TEOS chemicals plasma. However, when the liquid-phase. TEOS chemicals are injected into the process chamber without turning to a perfect gas phase, the liquid-phase TEOS chemicals are dropped onto the wafer surface to thereby form particles. Further, the conventional processes have the desired pause time to stabilize the TEOS chemicals injected into the process chamber. Accordingly, the TEOS chemicals injected into the process chamber floats up without reacting with plasma for the desired time, so that gas-phase TEOS chemicals are recombined to liquid-phase and dropped onto the wafer surface. The gas-phase TEOS chemicals are also stayed for the desired time without reacting with plasma, thereby allowing the amount of particles on the wafer surface to increase.

Therefore, there is a need for a PETEOS deposition method, which can minimize the amount of particles produced by TEOS chemicals, improve the quality of a PETEOS film, significantly shorten process time and significantly improve the reliability and productivity of a semiconductor device.

### SUMMARY OF THE INVENTION

The exemplary embodiments of the present invention provide an insulation film deposition method for a semiconductor device that minimizes the particles produced by TEOS chemicals.

Exemplary embodiments of the present invention provide an insulation film deposition method for a semiconductor device that improves the quality of a PETEOS film.

In addition, exemplary embodiments of the present invention provide an insulation film deposition method for a semiconductor device that can significantly shorten a process time.

Moreover, exemplary embodiments of the present invention provide an insulation film deposition method for a semiconductor device that significantly improves the reliability and productivity of the semiconductor device.

In accordance with an exemplary embodiment of the present invention, a thin-film deposition method for a semiconductor device is provided. The method includes injecting a process gas into a process chamber to deposit a thin film and forming a plasma atmosphere inside the process chamber while injecting the process gas to deposit a thin film on a semiconductor substrate. The thin film being formed by a reaction between the process gas and the plasma.

In accordance with an exemplary embodiment of the present invention, an insulation-film deposition method for a semiconductor device is provided. The method includes injecting a first process gas into a process chamber into which a semiconductor substrate is placed injecting a second process gas into the process chamber to which the first process gas flows; and forming a plasma atmosphere comprising the first process gas as a source gas inside of the process chamber while injecting the second process gas, to deposit an insulation film on the semiconductor substrate by a reaction between the first process gas plasma and the second process gas.

The first process gas is O₂, and the second process gas are TEOS chemicals.

### BRIEF DESCRIPTION OF THE DRAWINGS

Exemplary embodiments of the present invention can be understood in more detail from the following detailed description taken in conjunction with the accompanying drawings, in which:

FIG. 1 is a diagram illustrating a particle map produced on a wafer surface;

FIG. 2 is an expanded diagram for a wafer region (A) in which particles are produced;

FIG. 3 is a diagram illustrating a Plasma Enhanced Chemicals Vapor Deposition (PECVD) apparatus that is used to deposit a Plasma-Enhanced Tetraethylorthosilicate (PETEOS) film according to an exemplary embodiment of the present invention;

FIGS. 4A and 4B are a cross-sectional diagram illustrating a structure of a DRAM device for explaining a PETEOS film deposition method, that is performed through the PECVD apparatus, according to an exemplary embodiment of the present invention;

FIG. 5 is a flow chart illustrating a deposition process of the PETEOS film according to an exemplary embodiment of the present invention;

FIGS. 6A and 6B illustrate a deposition sequence of the PETEOS film according to the conventional art and an exemplary embodiment of the present invention;

FIGS. 7A and 7B illustrate a photograph and a graph for a wafer surface in the case where a pause time for TEOS chemicals is maintained to about 10 seconds;

FIGS. 8A and 8B illustrate a photograph and a graph for the wafer surface in the case where the pause time for TEOS chemicals is maintained to about 5 seconds; and

FIGS. 9A and 9B illustrate a photograph and a graph for the wafer surface in the case where the pause time for TEOS chemicals is maintained to about 0 seconds.

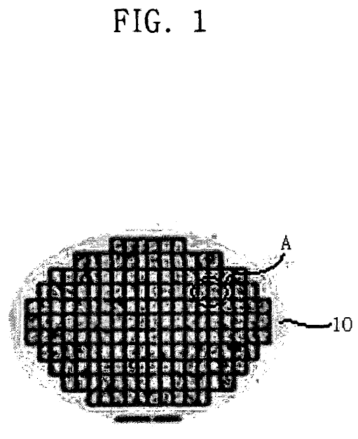

### DETAILED DESCRIPTION OF THE EXEMPLARY EMBODIMENTS

The aspects and features of the present invention and methods for achieving the aspects and features will be apparent by referring to the exemplary embodiments to be described in detail with reference to the accompanying drawings. However, the present invention is not limited to the exemplary embodiments disclosed hereinafter, but can be implemented in diverse forms. In the description of the exemplary embodiments of the present invention, the same drawing reference numerals are used for the same elements across various figures.

Hereinafter, exemplary embodiments of the present invention will be described in detail with reference to the accompanying drawings.

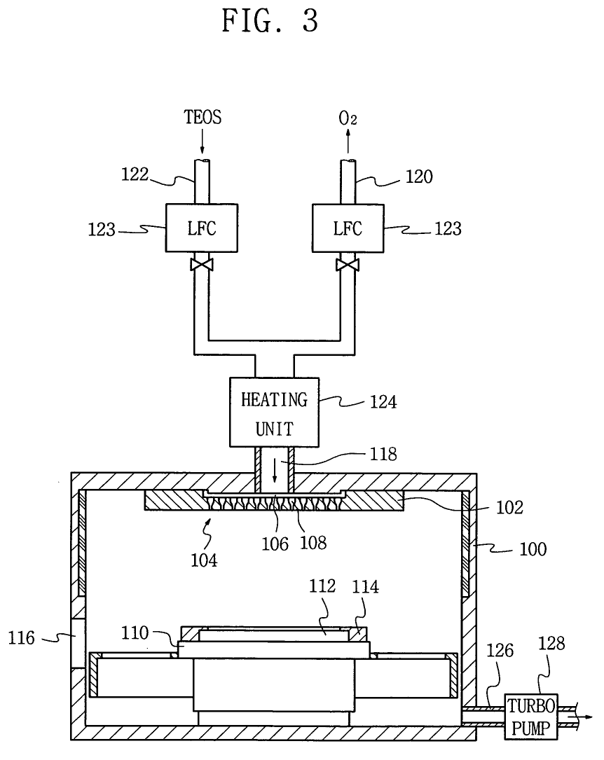

FIG. 3 is a diagram illustrating a PECVD apparatus that is used to deposit a PETEOS film according to an exemplary embodiment of the present invention, and shows a SQL model of Novellus systems, inc. The SQL model is a batch type CVD apparatus, which is produced to enable the PETEOS film to be consistently formed on six wafers to improve productivity.

Referring to FIG. 3, the PECVD apparatus includes a process chamber 100, e.g., a processing space in a sealed atmosphere. An upper electrode 102 for applying a radio frequency (RF) power is provided to an upper side of the process chamber 100. The RF power is more than approximately 350 watts (W) and applied to produce plasma inside the process chamber 100. A shower head 104 is provided to the upper side of the process chamber 100. The shower head 104 may be formed of a ceramic material having improved strength and insulation properties compared to a quartz material. The shower head 104 is provided with a buffer space 106 for temporarily storing gas being supplied through a gas supply pipe and a plurality of gas injection holes 108 for injecting the stored gas into the process chamber 100.

A lower electrode 110, to which the RF power is applied, is installed onto the bottom of the process chamber 100. An electrostatic chuck 112 for mounting a wafer is installed on the top of the lower electrode 110. A frequency of the RF power applied to the lower electrode 110 is a low frequency below approximately 700 W, and functions as a power source for forming plasma together with the RF power applied to the upper electrode 102. A clamp ring 114 is installed on an edge portion of the electrostatic chuck 112. This clamp ring is configured to have a ring shape to surround an edge portion of the wafer mounted on the electrostatic chuck 112. The wafer can be fixed at a predetermined location by the clamp ring 114. The clamp ring 114 extends a plasma region to the outside of the wafer, so that a whole region of the wafer can be affected by plasma. It is desirable that the clamp ring 114 is made of materials exhibiting high strength, corrosion resistance, acid-resistance, heat resistance, and impact resistance, such as resistant, for example, silicon carbide (SiC). A wafer loading opening 116 for loading the wafers to the top of the electrostatic chuck 112 is supplied to the lower region of the process chamber 100.

An upper portion of the shower head 104 is provided with a process gas injection hole 118 to which a process gas for a PETEOS film deposition process is injected. To deposit the PETEOS film, the PECVD apparatus includes a first process gas supply unit 120 for supplying TEOS chemicals, and a second process gas supply unit 122 for supplying O₂. An amount of each process gas supplied from the first and second process gas supply units 120 and 122 is controlled by a liquid flow controller (LFC) 123. The process gas injection hole 118 is provided with a heater unit 124 for heating liquid-phase TEOS chemicals supplied from the first process gas supply unit 120 to turn to a gas-phase.

An exhaust pipe 126 is provided to an outer side of the process chamber. The exhaust pipe 126 is connected to a turbo pump 128 for forming a vacuum inside the process chamber 100 and exhausting gas and particles inside the process chamber to the outside. The process chamber 100 performs a thin-film deposition process and is blocked from the outside. The turbo pump 128 is used to provide the inside of the process chamber 100 with a pressure which is suitable for the PETEOS deposition process. In other words, when the process gas for depositing the PETEOS film is injected inside the process chamber 100, an inner pressure of the process chamber 100 is temporarily increased. Accordingly, the increased pressure is controlled to a level suitable for the PETEOS deposition process using the turbo pump 128. More particularly, using the turbo pump, 128, the inner pressure of the process chamber 100 is maintained to a pressure required for the PETEOS film, and an unreacted gas inside the process chamber as well as reaction products produced during the deposition process are exhausted to the outside.

To deposit the PETEOS film using the PECVD apparatus, first, O₂ flows inside the process chamber 100. Second, the wafer is mounted on the top of the electrostatic chuck 112 of the process chamber 100, and then the TEOS chemicals are injected. During this time, the TEOS chemicals are heated by the heater unit to turn to a gas-phase. Accordingly, a minimum amount of the liquid-phase TEOS chemicals, which induce particles on the wafer, are injected inside the process chamber 100. The oxygen plasma atmosphere is formed inside the process chamber 100 by injecting the TEOS chemicals into the process chamber 100 and simultaneously applying the RF power to the upper electrode 102 and the lower electrode 110.

Unlike the conventional art, with the exemplary embodiments of the present invention, gas-phase TEOS chemicals are injected into the process chamber 100 and the plasma atmosphere is formed inside the process chamber 100 without requiring a separate pause time for stabilizing the TEOS chemicals after injecting the TEOS chemicals. According to exemplary embodiments of the present invention, when the gas-phase TEOS chemicals are injected into the process chamber 100 and plasma is formed inside the process chamber 100 while injecting the TEOS chemicals, particle production is reduced by minimizing the amount of the unreacted TEOS chemicals dropped onto the wafer surface, thereby allowing the quality of the PETEOS film to be improved.

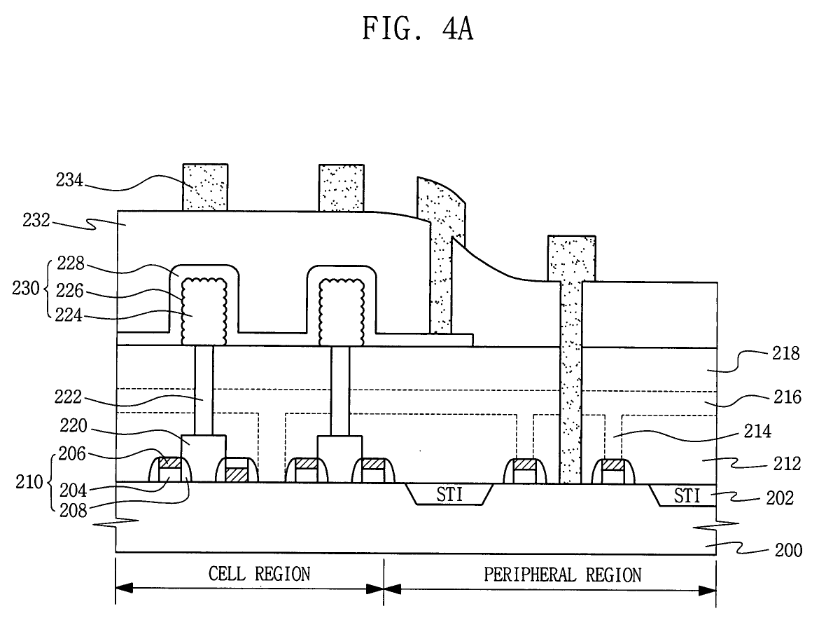

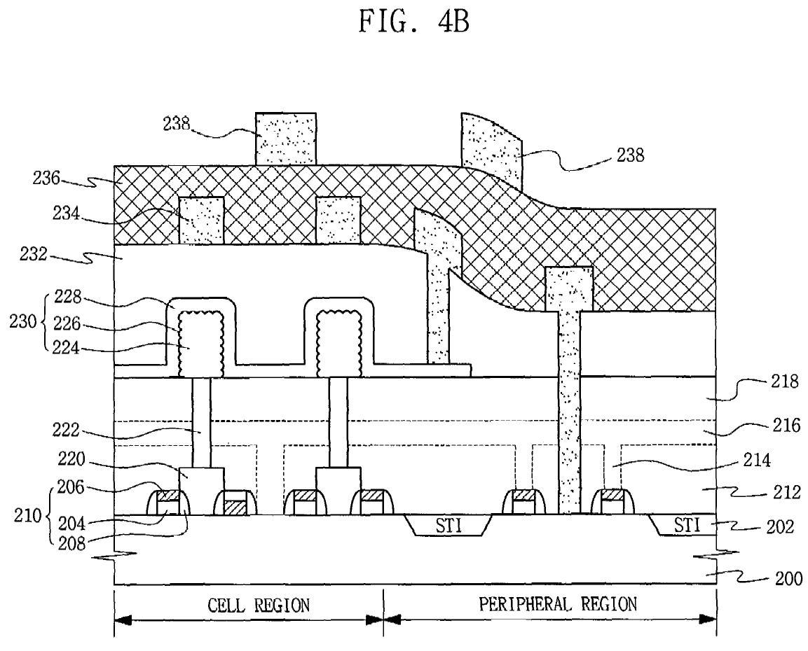

FIGS. 4A and 4B are a cross-sectional diagram illustrating a structure of a DRAM device for explaining a PETEOS film deposition method that is performed through the PECVD apparatus.

Referring to FIG. 4A, a semiconductor substrate 200 is divided into an active region and a field region by an isolation film 202 formed by a shallow trench isolation (STI) process. A gate electrode 210 is formed on a surface of the semiconductor substrate 200. The gate electrode 210 is formed, for example, by depositing a polysilicon film 204 and a silicide film 206 sequentially to improve electrical properties, patterning the polysilicon film 204 and the silicide film 206 to form a predetermined region, depositing an insulation film on the polysilicon film 204 and the silicide film 206, and forming a gate spacer 208 on both side walls of the polysilicon film 204 and the silicide film 206 by performing an anisotropy etching process such as an etch-back process. During this time, the silicide film 206 may be formed of, for example, a tungsten silicide film to improve the electrical properties of the gate electrode 210. The gate spacer 208 may be formed of, for example, a nitride film having the excellent insulation properties.

Dopants of group III (e.g., B) or group V (e.g., P, As) are implanted on the semiconductor substrate 200, on which the gate electrode 210 is formed, to thereby form source and drain regions inside the semiconductor substrate 200 surrounding the gate electrode 210. In the dopant-ion implantation process, the gate electrode 210 functions as a self-aligned ion implantation mask.

Next, a first interlayer insulation film 212 is doped on the source and drain regions. A surface of the first interlayer insulation film 212 is planarized by, for example, the etch back process or a chemical mechanical polishing (CMP) process. To prevent dopants implanted to the source and drain regions from being diffused to other regions by the following annealling process and prevent the profile from being distorted in a cleaning process, it is desirable that the first interlayer insulation film 212 is formed of, for example, a high density plasma oxide by a chemical vapor deposition (CVD) process.

Next, the first planarized interlayer insulation film 212 performs a photolithography process and an etching process to form a direct contact hole that extends to the drain region. A bit line 216 is formed by depositing a conductive material on a whole surface of the semiconductor surface including the direct contact hole. The bit line 216 is electrically connected to the drain region via the direct contact that is formed by filling the conductive material in the direct contact hole. Moreover, to improve the speed of the semiconductor device, the bit line 216 may be formed, for example, as follows: (1) forming a titanium silicide film using titanium; (2) forming a barrier layer on the titanium silicide film using nitride titanium; (3) forming a tungsten film on the barrier layer consisting of the nitride titanium; (4) forming a nitride film on the tungsten film; and (5) sequentially patterning the tungsten film, the nitride titanium film and the titanium silicide film using the nitride film as a etching mask.

A second interlayer insulation film 218 is formed of the high density plasma oxide which can be deposited on a whole surface of the bit line 216 at low temperature. An upper surface of the second interlayer insulation film 218 is planarized, for example, by the each back process or the CMP process. The second interlayer insulation film 218 performs the photolithography process and the etching process to form a buried contact hole that extends to the source region. A buried contact 222 is formed by filling the conductive materials in the buried contact hole. During this time, the buried contact 222 is electrically connected to the source region via a landing pad 220 to assure an align margin.

Next, a capacitor 230, which is electrically connected to the buried contact 222, is formed. The capacitor 230 is configured of a lower electrode 224, a high dielectric film 226 and an upper electrode 228. The capacitor 230 forms the lower electrode 224 by depositing and patterning the polysilicon film. During this time, the lower electrode 224 may be implemented with, for example, a stack type or a cylinder type to increase capacitance, and also be implanted with a hemispherical grain type. Next, by forming the high dielectric film 226 on a surface of the lower electrode 224 and then forming the upper electrode 228 on a surface on the high dielectric film 226, the capacitor 230 is completed. The high dielectric film 226 may be formed, for example, from one of tantalum oxide (Ta₂O₅), aluminum oxide (Al₂O₃) formed by an atomic deposition or an ONO film consisting of a stacked structure of a nitride film-oxide film-nitride film. The upper electrode 228 may be formed, for example, of a double-film structure consisting of the polysilicon or the nitride titanium and the polysilicon.

A third interlayer insulation film 232 is deposited on the whole surface of the semiconductor substrate 200 on which the capacitor 230 is formed. A metallization process is performed on a cell region and a peripheral region, on which the capacitor 230 is formed, to form a first metal 234 on the upper electrode 228 and the active region of the peripheral region.

Referring to FIG. 4B, a fourth interlayer insulation film is deposited on the whole surface of the semiconductor substrate 200 on which the first metal 234 is formed. The fourth interlayer insulation film is the inter-metal dielectric (IMD) and formed of the PETEOS film 236 using the PECVD apparatus shown in FIG. 3. A second metal 238 is formed on the PETEOS film 236 by performing the metallization process.

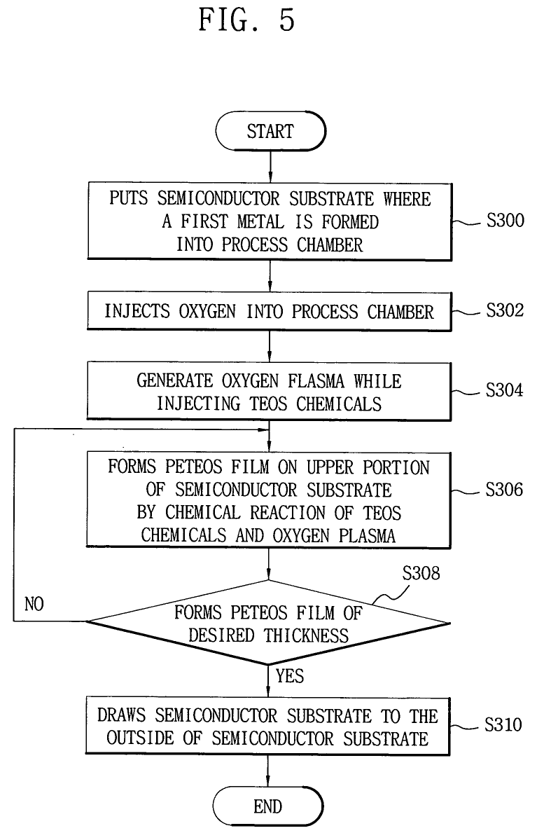

The PETEOS film deposition process will be explained in detail with reference to FIG. 5.

FIG. 5 is a diagram illustrating a deposition process of the PETEOS film using the PECVD apparatus according to an exemplary embodiment of the present invention.

Referring to FIG. 5, a process for forming the PETEOS film on the semiconductor substrate 200, on which the first metal 234 is formed, is as follows.

The semiconductor substrate 200, on which the first metal 234 is formed, is introduced inside the process chamber 100 of the PEVD apparatus S300. For example, the semiconductor substrate 200 is mounted on the top of the process chamber 100.

Next, O₂ of about 1100 standard cubic centimeters per minute (SCCM) is injected into the process chamber 100 through the first process gas supply line 120 S302.

O₂ plasma is produced by injecting the TEOS chemicals at a flow rate of about 0 to about 3 standard liters per minute (slm), such as for example about 2.4 slm, and simultaneously applying the RF power to the upper electrode 102 and the lower electrode 110 S304. For example, to form O₂ plasma flowing into the process chamber 100, the power of about 350 W is applied to the upper electrode 102, and the power of about 700 W is applied to the lower electrode 110. An inter pressure of the process chamber 100 is maintained to about 2.0 torr, and the temperature is maintained to about about 300 to about 400° C. As a result thereof, O₂ is resolved into O⁺ ions with a positive charge (+), electrons with a negative charge (−), and O* radical of a neutral particle with no electric charge, to form the plasma state.

“producing the oxygen plasma while injecting TEOS chemicals” may have the following meanings. First, the oxygen plasma is produced by applying the RF power while initiating the injection of the TEOS chemicals into the process chamber 100. Second, the oxygen plasma is produced by applying the RF power just after finishing the injection of a fixed amount of the TEOS chemicals into the process chamber 100. The exemplary embodiments of the present invention prevent the TEOS chemicals injected into the process chamber 100 from floating at a state that is not reacted with the oxygen plasma.

As described above, if the oxygen plasma is formed by applying the RF power while injecting the TEOS chemicals into the process chamber 100, oxygen radical and the TEOS chemicals are chemically combined with each other, in which the oxygen radical is one of materials constituting the oxygen plasma. Accordingly, the PETEOS film 236 functioning as the IMD film is formed on the semiconductor substrate 200 on which the first metal 234 is formed as shown in FIG. 4B S306. During this time, the PETEOS film 236 is deposited to a thickness of about 100 angstroms (Å) per 0.3 seconds under the process chamber conditions S306.

The PETEOS film 236 is then checked to see whether it has been formed on the upper portion of the semiconductor substrate 200 having a desired thickness so as to function as the IMD film S308. As a result of the above-mentioned check, if the PETEOS film 236 is not formed to the desired thickness, return to S306. If the PETEOS film 236 is formed to the desired thickness, the semiconductor substrate 200 is drawn out from the process chamber 100. Next, the semiconductor device is completed by performing the metallization process on the semiconductor substrate 200, on which the PETEOS film 236 is formed, to form the second metal 238.

In S304 of the PETEOS deposition process, the oxygen plasma is produced by applying the RF power while injecting the TEOS chemicals into the process chamber 100.

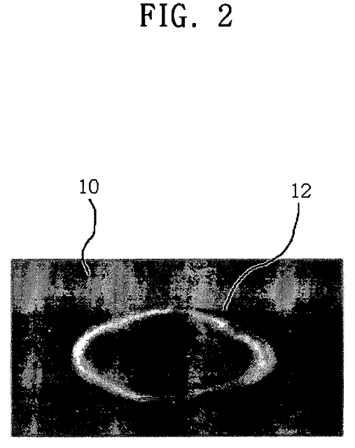

Usually, the TEOS chemicals are turned into the gas-phase by heating the TEOS chemicals of the liquid-phase using the heating unit 124 (e.g., HIM heater), and then the TEOS chemicals of the gas-phase is injected into the process chamber 100 through the process gas supply hole 118. However, if the temperature of the HIM heater is not sufficient for vaporizing the TEOS chemicals of the liquid-phase into the TEOS chemicals of the gas-phase, both the TEOS chemicals of the liquid-phase and the TEOS chemicals of the gas-phase may be injected into the process chamber 100. As mentioned above with regard to the conventional art, if the pause time (about 10 seconds) for stabilizing the TEOS chemicals exists, the TEOS chemicals injected into the process chamber 100 are dropped onto the wafer surface to thereby induce particles on the wafer surface. During this time, the TEOS chemicals dropped onto the wafer surface are divided into \textcircled{1} TEOS chemicals that is the liquid phase originally from when the TEOS chemicals are injected into the process chamber and \textcircled{2} TEOS chemicals that are recombined into the liquid-phase for the pause time of about 10 seconds after the TEOS chemicals of the gas phase is injected into the process chamber. As such, if the TEOS chemicals of the liquid phase are inside the process chamber, the TEOS chemicals of the liquid phase are dropped onto the wafer surface by their own weight. As a result thereof, particles, e.g., defects of the petal shape with a size of about 0.2 to about 0.5 micrometers (μm) as shown in FIG. 2, are formed on the wafer surface, thereby lowering the quality of the PETEOS film. The TEOS chemicals of the gas phase may also induce smaller amounts of particles than the TEOS chemicals of the liquid phase by the contact with the wafer surface.

However, as describe above, when the oxygen plasma is produced by applying the RF power while injecting the TEOS chemicals into the process chamber, that is, when the oxygen plasma is produced without having the pause time for stabilizing the TEOS chemicals, a high quality of the PETEOS film is deposited on the wafer surface by an active chemical reaction between the TEOS chemicals and the oxygen radical. According to the exemplary present invention, when the oxygen plasma is produced by applying the RF power while injecting the TEOS chemicals into the process chamber, the quality of the PETEOS film deposited on the wafer surface is improved. The quality of the deposited PETEOS films is improved for at least the two reasons described below.

First, TEOS chemicals of the gas phase reacts with the oxygen radical (O*) having improved reactivity as soon as they are injected into the process chamber to form the high quality PETEOS film on the wafer surface (conventionally, TEOS chemicals of the gas phase is dropped onto the wafer surface by being recombining to TEOS chemicals of the liquid phase, thereby inducing particles). TEOS chemicals of the liquid phase also help form the PETEOS film on the wafer by the oxygen radical with the improved reactivity.

Second, the oxygen plasma formed by a high frequency power such as the RF power has a high state of energy. Thus, smaller unit TEOS chemicals of the gas phase are formed by resolving and vaporizing TEOS chemicals of the liquid phase by the oxygen plasma. Accordingly, the particle production is minimized by reducing the amount of the TEOS chemicals of liquid-phase dropped onto the wafer surface.

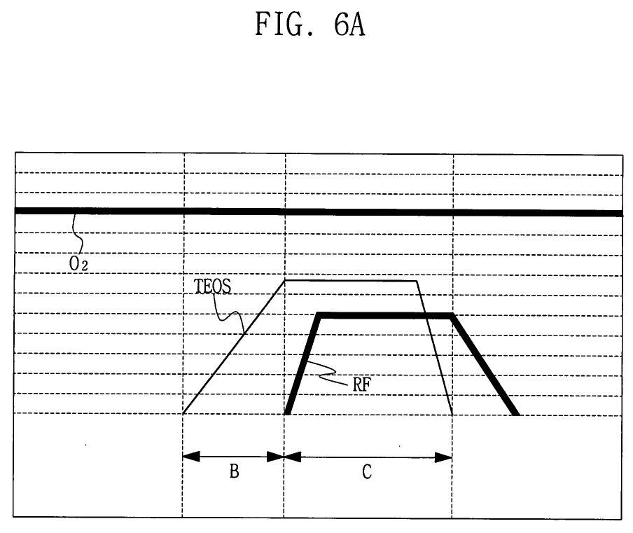

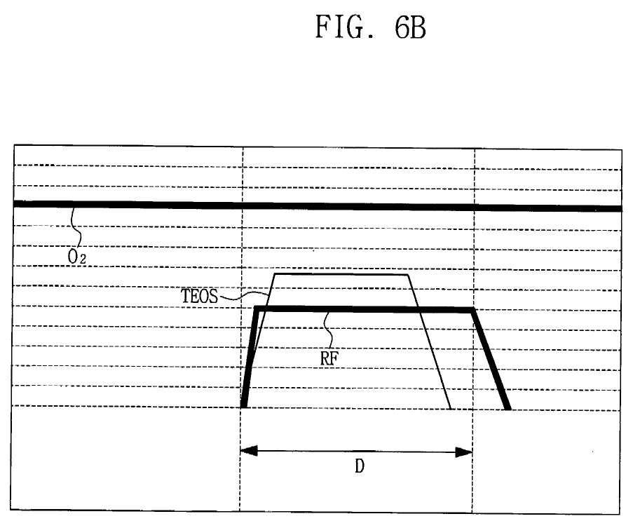

According to exemplary embodiments of the present invention, the oxygen plasma atmosphere is formed by applying the RF power while injecting the TEOS chemicals into the process chamber, thereby allowing high quality of PETEOS film to be deposited. The PETEOS film deposition process sequence according to the exemplary embodiments of the present invention will be explained in comparison with that of the conventional art with reference to FIGS. 6A and 6B.

FIG. 6A illustrates a deposition sequence of the PETEOS film according to the conventional art.

Referring to FIG. 6A, conventionally, to form the PETEOS film as the IMD for insulating between the lower metal and the upper metal, the TEOS chemicals are injected into the process chamber to which O₂ flows. Next, to stabilize the TEOS chemicals injected into the process chamber, the pause time (B) of about 10 seconds is provided. Next, by applying the RF power to produce the oxygen plasma, the PETEOS film is deposited on the upper portion of the semiconductor substrate for a time (C). However, according to the conventional art, the TEOS chemicals are dropped onto the wafer surface for the pause time (B) of about 10 seconds for stabilizing the TEOS chemicals injected into the process chamber, thereby allowing particles to be produced on the wafer surface. The TEOS chemicals include \textcircled{1} TEOS chemicals that is the liquid phase originally from when the TEOS chemicals are injected into the process chamber and \textcircled{2} TEOS chemicals that is recombined to the liquid-phase for the pause time of about 10 seconds after the TEOS chemicals of the gas phase is injected into the process chamber.

On the contrary, FIG. 6B illustrates a deposition sequence of the PETEOS film according to the exemplary embodiments of the present invention.

Referring to FIG. 6B, the oxygen plasma is produced by applying the RF power while injecting the TEOS chemicals into the process chamber to which O₂ flows. In other words, the pause time for stabilizing the TEOS chemicals injected into the process chamber is skipped. As a result thereof, as shown in a reference mark (D), a high quality PETEOS film is deposited on the upper portion of the semiconductor substrate by an active reaction between the oxygen radical and plasma while injecting the TEOS chemicals into the process chamber.

Consequently, according to the conventional art, by having the pause time for stabilizing the TEOS chemicals, particles are produced on the wafer surface by non-reaction TEOS chemicals.

However, according to the exemplary embodiments of the present invention, the pause time for stabilizing the TEOS chemicals is skipped, and the plasma is produced while injecting the TEOS chemicals into the process chamber, thereby allowing the amount of non-reaction TEOS to be minimized. Consequently, particles produced by non-reaction TEOS chemicals on the wafer surface are minimized by minimizing the amount of the non-reaction TEOS chemicals, thereby allowing a high quality PETEOS film to be deposited.

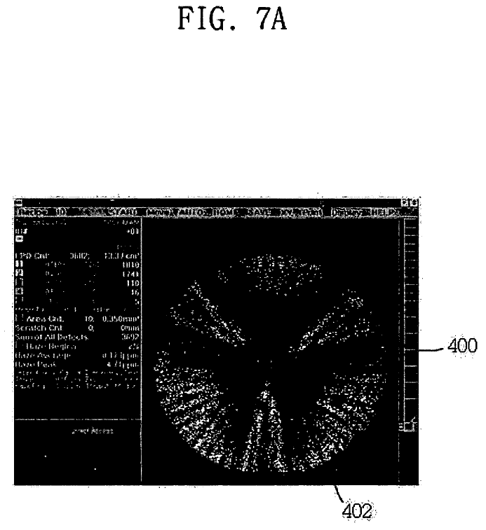

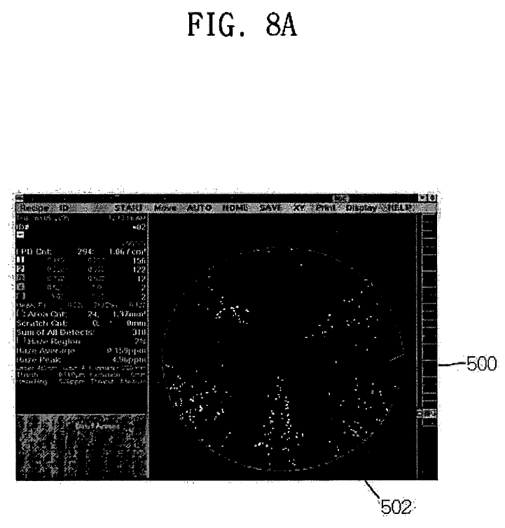

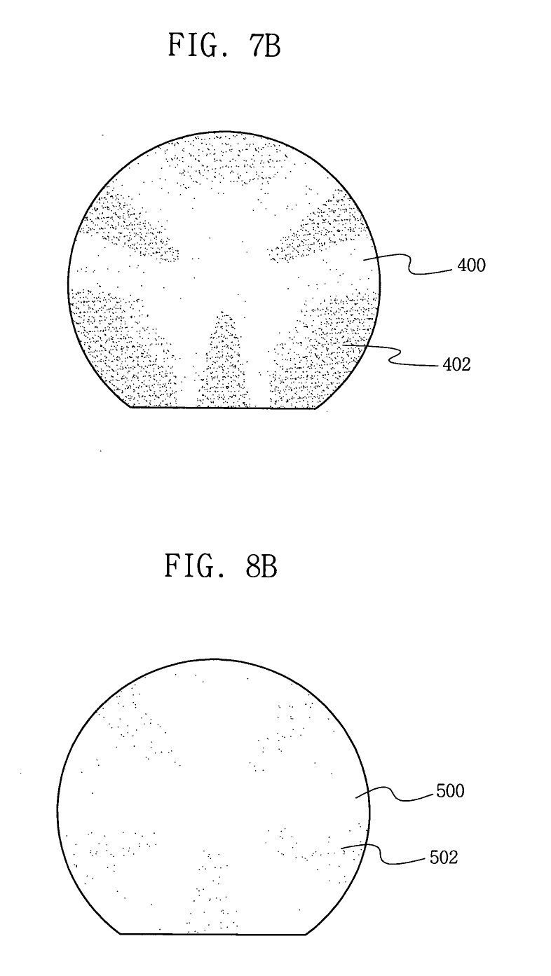

Hereafter, FIGS. 7A to 9B illustrates a particle production distribution on the wafer surface according to the change of the pause time for the TEOS chemicals.

FIGS. 7A and 7B illustrate a photograph and a graph for a wafer surface in the case where a pause time for TEOS chemicals is maintained to about 10 seconds.

As shown in FIGS. 7A and 7B, when the PETEOS film is formed after maintaining the pause time for about 10 seconds, particles 402 produced by non-reaction TEOS chemicals are densely distributed over the whole surface of the wafer 400. As such, if particles 402 are produced over the whole surface of the wafer 400, the reliability and productivity of the semiconductor device are substantially decreased by the decrease in the quality of the PETEOS film.

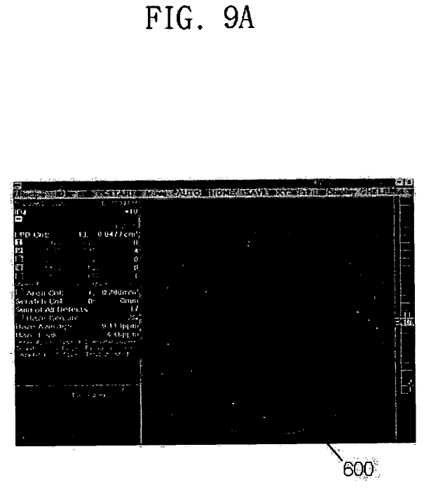

FIGS. 8A and 8B illustrate a photograph and a graph for the wafer surface in the case where the pause time for TEOS chemicals is maintained to about 5 seconds.

As shown in FIGS. 8A and 8B, the particle distribution region is significantly reduced in comparison with that shown in FIGS. 7A and 7B. However, particles 502 produced by the non-reaction TEOS chemicals are still distributed over the whole surface of the wafer 500. Accordingly, even though the pause time is reduced to about 5 seconds, particles 502 are still induced on the wafer surface. Consequently, it is difficult to obtain a high quality PETEOS film.

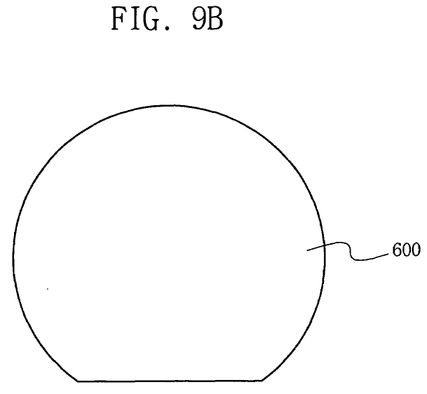

FIGS. 9A and 9B illustrate a photograph and a graph for the wafer surface in the case where the pause time for TEOS chemicals is maintained to about 0 seconds.

As shown in FIGS. 9A and 9B, when the plasma is produced without the pause time as soon as the TEOS chemicals are injected into the process chamber, particles produced by the non-reaction TEOS chemicals are hardly produced on the whole surface of the wafer 600.

According to the exemplary embodiments of the present invention, when the PETEOS film functioning as the IMD is deposited, the oxygen plasma atmosphere is formed by applying the RF power while injecting the TEOS chemicals into the process chamber. Accordingly, the TEOS chemicals are injected into the process chamber and simultaneously react with the oxygen radical, without the time floating in the inside of the process chamber in the non-reaction state with the oxygen radical. As a result thereof, the non-reaction TEOS chemicals floating inside the process chamber are not dropped onto the wafer surface, and thus particles are not induced, thereby allowing a high quality PETEOS film to be deposited. Moreover, the insulation capability of the PETEOS film, which functions as the IMD, is significantly improved, thereby allowing the semiconductor device to have improved electrical properties.

Further, particles produced on the wafer surface are reduced, thereby allowing the working ration of the facilities to be improved by lengthening a PM period such as a facilities cleaning.

Further, the pause time for stabilizing the TEOS chemicals injected into the process chamber is skipped, thereby allowing the productivity to be improved, resulting in reduction of total process times (e.g. about 10 seconds per wafer).

The PETEOS film deposition method, according to the exemplary embodiments of present invention, can obtain the high quality of the PETEOS film without additional process or facilities. Accordingly, the PETEOS film deposition method of the exemplary embodiments of the present invention is beneficial when fabricating highly-integrated semiconductor devices.

The PETEOS film deposition method, according to the exemplary present invention, has been explained with regard to DRAM memory devices. However, this is merely one exemplary embodiment for explaining core technology of the present invention, and may be widely applied to various memory devices including the DRAM. Further, the exemplary embodiments of the present invention may also be applied to material films other than the IMD, including the ILD region.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A thin film deposition method for a semiconductor device, comprising:
injecting a process gas for a thin film deposition into a process chamber; and
forming a plasma atmosphere inside the process chamber while injecting the process gas to deposit a thin film on a semiconductor substrate, the thin film being formed by a reaction between the process gas and the plasma.

2. The thin-film deposition method of claim 1, wherein the process gas is comprised of tetraethylorthosilicate (TEOS) chemicals.

3. The thin-film deposition method of claim 2, wherein the plasma is oxygen plasma that is formed of an oxygen source.

4. The thin-film deposition method of claim 3, wherein the thin film is a plasma enhanced tetraethylorthosilicate (PETEOS) film formed by a chemical combination of an oxygen radical and the TEOS chemicals.

5. The thin-film deposition method of claim 4, wherein the process gas is injected into the process chamber in a gas phase.

6. The thin-film deposition method of claim 1, wherein the plasma atmosphere is formed inside the process chamber as soon as one of the process gas injection is started, or as soon as the process gas injection is completed.

7. An insulation deposition method for a semiconductor device, comprising:
injecting a first process gas into a process chamber into which a semiconductor substrate is placed;
injecting a second process gas into the process chamber to which the first process gas flows; and
forming a plasma atmosphere comprising the first process gas as a source gas inside of the process chamber while injecting the second process gas, to deposit an insulation film on the semiconductor substrate by a reaction between the first process gas plasma and the second process gas.

8. The insulation film deposition method of claim 7, wherein the first process gas is oxygen (O₂).

9. The insulation film deposition method of claim 8, wherein the second process gas is comprised of chemicals containing silicon.

10. The insulation film deposition method of claim 9, wherein the second process gas is comprised of tetraethylorthosilicate (TEOS) chemicals.

11. The insulation film deposition method of claim 10, wherein the insulation film is a plasma enhanced tetraethyl orthosilicate (PETEOS) film formed by a chemical combination of an oxygen radical and the TEOS chemicals

12. The insulation film deposition method of claim 11, wherein the second process gas is injected into the process chamber in a gas phase.

13. The insulation film deposition method of claim 12, wherein the second process gas is heated by a heating unit to turn to the gas phase, before being injected into the process chamber.

14. The insulation film deposition method of claim 13, wherein the first process gas is injected into the process chamber at about 1100 standard cubic centimeters per minute (SCCM).

15. The insulation film deposition method of claim 14, wherein the second process gas is injected into the process chamber in a range of about 0 to about 3000 standard cubic centimeters per minute (SCCM).

16. The insulation film deposition method of claim 15, wherein the second process gas is injected into the process chamber at about 2400 standard cubic centimeters per minute (SCCM).

17. The insulation film deposition method of claim 16, wherein the plasma is formed by applying a radio frequency (RF) power of about 350 watts and about 700 watts to an upper electrode and a lower electrode respectively, and maintaining a pressure of about 2.0 torr and a temperature of about 300 to about 400° C.

18. The insulation film deposition method of claim 7, wherein the plasma atmosphere is formed inside the process chamber as soon as one of the second process gas injection is started, or as soon as the second process gas injection is completed.

19. The insulation film deposition method of claim 7, wherein the first process gas is injected into the process chamber before putting the semiconductor substrate into the process chamber.

20. An insulation film deposition method for a semiconductor device, comprising:
injecting oxygen forming plasma into a process chamber into which a semiconductor is placed;
injecting a process gas containing silicon into the process chamber to which oxygen flows;
forming oxygen plasma by applying a radio frequency (RF) power to the process chamber while injecting the process gas; and
depositing a silicon oxide film on the semiconductor substrate by a chemical reaction of oxygen and silicon in the process gas.
